(19) United States
(12) Patent Application Publication
(10) Pub. No.: US 2006/0247133 A1
(43) Pub. Date: Nov. 2, 2006

(54) Superconducting carbon 12 atomic strings and methods of manufacture of cables containing parallel strings

(76) Inventor: Robert W. Beckwith, Clearwater, FL (US)

Correspondence Address: Leo J. Aubel, 111 Rivershire Lane, Lincolnshire, IL, 60069, US

(21) Appl. No.: 11/476,248

(22) Filed: Jun. 28, 2006

Related U.S. Application Data
(63) Continuation-in-part of application No. 10/983,380, filed on Nov. 8, 2004.
(63) Continuation-in-part of application No. 11/073,156, filed on Mar. 5, 2005.

(51) Int. Cl. H01L 39/24

(52) U.S. Cl. 505/100

(57) ABSTRACT

A string of super-dense carbon atoms forms a superconductor unaffected by temperature changes over a wide range. Using molecular beam epitaxy technology, a number of such carbon atomic strings are connected in parallel and encased in a plastic which forms nanotubes around each string having a negatively charged inner surface on each tube formed. The superconducting electrons travel in the cylindrical space between the inside of the nanotubes and the outside of the carbon strings. Cables carrying 20,000 amperes of electric current and withstanding 81,300 pound pull are projected. Strings connect to super-dense diamond plates at the two ends of a cable which plates both carry electric current and carry the pulling force. Superconducting belts excite iron pipes sending sparks into storm clouds for withdrawing energy from the clouds.

This patent application is a continuation in part of application Ser. No. 11/073,156 filed on Mar. 5, 2005 which was a continuation in part of application Ser. No. 10/983,380 filed on Nov. 8, 2004, all with no change in title.

### BACKGROUND OF THE INVENTION

The electric utility industry is currently using superconductors which require expensive cryogenic cooling.

An overall look at efficiencies of electric power systems in the United States leads to estimates that 10 to 20 percent of prime mover input energy is consumed in electrical losses before it is received by users of electric energy. At 10 cents per kilowatt hour this computes to as much as $50 to $100 billion per year that could possibly be saved by use of loss-less superconductors that require no cryogenic cooling.

Even more savings will result from the use of loss-less superconductors in end use devices. Use of cables of this invention in cities of the future could eliminate the present interconnected electric power network of generation, transmission and distribution of electric energy. Use of energy per person in such cities may be reduced by a factor of 1000. All of this contributes to reduction in global warming.

### New Laws of Nature

1a. A strong electric current flows through the magnum of the Earth more or less on the equatorial plane of the Earth. The current is generated by the rotation of the Earth on its axis through the magnetic field of the Sun. The current is modulated at about 8.6 Hz.
1b. Other currents flow parallel to the axis of the Earth at its equator and in and out of the ionosphere surrounding the Earth.

These two currents act together to form the north and south magnetic poles of the Earth.

Further these two currents form vortices as they flow across each other in the magnum under the surface of the earth. These vortices may add to the power of tornados and hurricanes and may modulate the magnetic poles of the Earth.
2. Electro-mechanical resonant channels exists between the rocky underside of the Earth's crust and the hot plasma of molten rock as it touches the solid rock. The solid rock is a good carrier of mechanical vibration but a poor conductor of electric current. The magnum, on the other hand, is an excellent conductor of electricity. The resonant channels appear to be complex in their geometry.

The resonant channels have bandwidths of about 2 Hz around a center frequency of about 10 Hz. Electro-mechanical signals from volcanos and earthquakes travel between far distant points with little apparent loss via the channel over which they travel.

As far as is known by the present inventor, new laws of nature 1a, 1b, and 2 have not been recognized by others. The present invention is in part based on these new laws of nature.
3. Using heavy electric currents a volume of space can be removed from universal space and placed in its own divided space. The divided space and its contents can then be made to levitate, teleport or time travel in zero time.

Law of nature 3 is used by others. It is also used in the present invention.

### REFERENCES

1. UNITED STATES SHIP CARDINAL (MHC 60)

COMMISSIONING CEREMONY Oct. 18, 1997 Alexandria, Va.

Transferred, 1 Sep. 2000 from the Naval Reserve Force to the active fleet for permanent deployment to the Persian Gulf. Home port, Manama, Bahrain.
2. Current Fleet of Mine Warfare Ships, one sheet. From the internet at http://www.navy.mil/palib/cno/n75/Htm/4000PopI.htm
3. U.S. Pat. No. 4,042,196 METHOD AND APPARATUS FOR TRIGGERING A SUBSTANTIAL CHANGE IN EARTH CHARACTERISTICS AND MEASURING EARTH CHANGES, Filed by Neil M. Brice on Jul. 21, 1972 and issued Aug. 16, 1977; assigned to Cornell Research Foundation, Ithaca N.Y.
4. U.S. Pat. No. 4,686,605, METHODS AND APPARATUS FOR ALTERING A REGION IN THE EARTH'S ATMOSPHERE, IONOSPHERE AND MAGNETOSPHERE, filed by Dr. Bernard J. Eastlund, on Jan. 10, 1985, and issued Aug. 11, 1987; assigned to APTI INC., Los Angeles, Calif.
5. PHENOMENOLOGICAL ANALYSIS OF FORCES IN HURRICANE DYNAMICS, A PAPER BY Robert A. Dickerson, PhD, Independent Engineering Consultant, POB 11733 Lake Tahoe, Nev. 89448; email Bob@buylaketahoe.com
6. Provisional patent application 60/809,262. APPARATUS AND METHODS FOR OBTAINING INFORMATION ABOUT THE EARTH'S EXTRA LOW FREQUENCIES (ELF) SIGNALS FROM A HOLE-IN-THE-GROUND (HITG). Filed in the name of the present inventor on May 30, 2006

Reference 1 describes the USS CARDINAL (MHC-62), one of a class of Mine Warfare Ships capable of Levitation, Teleportation and Time Travel. Mrs. Beckwith and I visited the Cardinal as members of a group of about 30 that were the first aboard on Sunday morning, Armed Forces Weekend, 1998. We had spent Saturday at McDill Air base in Tampa looking at airplanes and saw a small notice of the inspection trip that we attended on Sunday.

In first touring the Savannah, an ocean going wooden hulled minesweeper, we were told ‘wait until you see the Cardinal, that's where all the action is’. The Cardinal and other mine warfare ships of the Osprey class were known throughout the Navy as the most choice assignment in the Navy.

When invited aboard the Cardinal, the capabilities of the ship were made public. We were told that on Friday they were busy in the Persian Gulf. Sometime overnight they ‘blinked’, ie teleported to Tampa Bay and from there traveled on the surface to the Tampa Navy dock. The mission control officer, Lieutenant Joe. Sinninger, showed us his flat panel display with a one line diagram of the surrounding area and an Icon showing the Cardinal's position. He said that the action was the same as during training and that the only way that he knew that they had changed position from the Persian gulf was when his display ‘blinked’ from one showing the Persian Gulf to the one that we saw showing the position at the Tampa Navy dock. Moreover, he said that Monday morning they would blink to a port in Japan where they were to clear some mines.

A cabinet, said to contain their positioning computer, separated the mission control officer from the operations and maintenance officer. The maintenance officer told us that sometimes they had to bring a new form of mine up and stow it in a container on deck.

The ARVN (Automatic Retrieval Vehicle Navy), is a highly automated tethered submarine. ARVNs are outlined under odd page numbers of the Reference 1 MHC Commissioning booklet. A second device, outlined under even page numbers, is used to bring mines up for taking back to base for reverse engineering. He said their operation became dicey when they had to use one of the second devices to bring a mine on deck. They had to go to the visible, real time, mode while on deck with unfriendlies bearing down on them in gunboats. Whenever possible they blinked ahead a bit in time where others couldn't see them since they were not there yet.

The ARVN driver said that he could disassemble a sophisticated mine and set an explosive to blow it up. Mines were designed to be exploded and reset themselves for further destructive explosions.

Various crew members told the group of the danger that would exist if they had anything made of iron in their clothing. A staple or paper clip could be deadly, propelled by the high magnetic field through their bodies when they teleported to a new position.

In a trip below deck we went past an assembly of cabinets each the size of a double refrigerator. The cabinet was marked ‘Marconi Degausing Equipment’. An LED on the panel was labeled ‘Teleportation Mode’. It was, of course, unlighted at the time.

We were shown the Diesel Engine drive built by Intermarine SpA of Le Spezia Italy. We were told that the engine had no iron or other magnetic materials in its construction. We were also told that the ship could be dropped 100 feet upside down into the water without damage.

Note the Ships Characteristics on page 39 of the Commissioning Book. The picture on the back cover of the book shows the Cardinal turning within its own length using the two Voith Schneider Cycloidal Propellers. We were told that the maximum safe operating depth for the Cardinal was 3000′ and that the maximum speed forward was 10 knots.

Before leaving the ship at the end of our visit I remarked is to Commander Sheehan that no attempt was made to hide their ability to become invisible and to teleport long distances around the world. His response was that there was no need not to tell the truth since most people did not believe what they were told!

Construction of the ship use ‘a solid, continuous monocoque structure laminated from a special fiberglass and resin. Belts of the special materials is shown being installed on pages 21 and 22. The tremendous currents required for teleportation are carried by carbon superconductors requiring no cryogenic cooling. The resin surrounding the carbon superconducting strings is Rogers RT Duroid 580 or equivalent.

Material in reference patents 3. and 5. suggest currents both natural and man made that contribute to forming the magnetic poles of the Earth. It is also apparent that currents flow underground between the northern and southern auroral zones and parallel to the axis of the Earth, to support the rule that currents, like a rubber band, have no beginning or end.

### SUMMARY OF THE INVENTION

A super-dense form of a carbon diamond is described as a cubic form of carbon in which the magnetic directions of the atomic core, acting in the first way for combining bar magnets, are reversed in checkerboard fashion over layers of the diamond. Magnetic force lines circulate between reversed pairs of carbon atoms pulling them together with considerable force in a first method of forming hardness of the diamond.

The layers of the super-dense diamond are further arranged with magnetic fields attracting pairs of atoms end to end. This uses the second way that bar magnets can attract each other.

In this form the carbon atoms have collapsed to a state where their valence electron paths touch. A magnetic field of 8.13 pounds force is produced between the nuclei of the atoms forming a super-dense diamond having a cubic lattice of carbon atoms.

Extreme temperatures and pressures applied to a conventional carbon diamond are required to form a super-dense carbon diamond. Alternatively super-dense diamonds can be formed using molecular beam epitaxy (MBE) deposition technology.

A mono layered single dimensional super-dense carbon diamond forms a superconducing string with magnetic directions of atoms alternating 180° along the string. One electron per atom is left over in the single dimensional string for carrying superconducting electric currents.

Single superconducting strings of carbon atoms carry approximately one half ampere of current and will support 8.13 pounds of pull. It is estimated that ribbon cables with 10,000 parallel strands could carry 20,000 amperes of electric current and hold tensional loads of up to 81,300 pounds.

To establish a frame of reference in size, please consider that both single strings and theoretical 100×100 stacks of 10,000 parallel strings are smaller than can be seen using ordinary light!

In practice loosely bonded electrons flow between the exterior of the carbon strings and the inside surface of Durand plastic used to form nanotubes around each string in a multi-string cable. The special teflon like plastic forms negatively charged surfaces along the inside of the nanotubes effectively repelling the superconducting electrons into a cylindrical pathway between the plastic tube and the atomic string.

Cables have ribbons of superconducting carbon strings terminated by super-dense carbon diamond plates at both ends. These plates allow superconducting currents to flow in either direction over the ribbons of carbon strings. The plates can also be used as pulling attachments for mechanical loads.

Belts of carbon superconductors are wrapped around stealth craft to allow them to move forward in time so as to become invisible and to teleport from point to point on Earth. Levitation is also accomplished as needed.

A sea level clockwise loop of superconducting cable is suggested for removing energy from counterclockwise rotating storms to prevent them from forming hurricanes. Counterclockwise belts are suggested for the Atlantic Ocean to form small hurricanes to remove heat from the tropics to maintain a balanced and non destructive planetary heat balance.

### BRIEF DESCRIPTIONS OF THE DRAWINGS

FIG. 1a A view in the plane of touching valence electrons of six carbon atoms with alternating magnetic directions.

FIG. 1b A view of the carbon atoms of FIG. 1a rotated 90° so as to show electron flow in two directions releasing one electron from each atom for forming superconductivity.

FIG. 1c A view of a superconducting carbon diamond from the top, edge and side.

FIG. 2a A view depicting the first way that bar magnets attract each other.

FIG. 2b A view depicting the second way that bar magnets attract each other.

FIG. 3a A view of 10 carbon atoms forming a superconductive string contained in a plastic nanotube.

FIG. 3b A cross section of the carbon superconducting string in a plastic nanotube.

FIG. 4a An end view of a superconducting cable carrying many superconducting carbon strings, each in a plastic nanotube.

FIG. 4b A side view of a superconducting carbon diamond end plate connected to the cable of FIG. 4a.

FIG. 5. A drawing from U.S. Pat. No. 4,042,196 with inventive portions removed.

FIG. 6 A drawing showing a frequency spectrum obtained from a hole in the ground.

FIG. 7 A drawing showing the first way of using dc currents for forming a magnetic pole.

FIG. 8 A drawing showing the second way of using dc currents for forming a magnetic pole.

FIG. 9a A top view of a superconducting belt for a system capable of drawing energy from a storm cloud.

FIG. 9b A side view of a system using a superconducting belt for drawing energy from a storm cloud.

### DETAILED DESCRIPTION OF THE PREFERRED EMBODIMENT

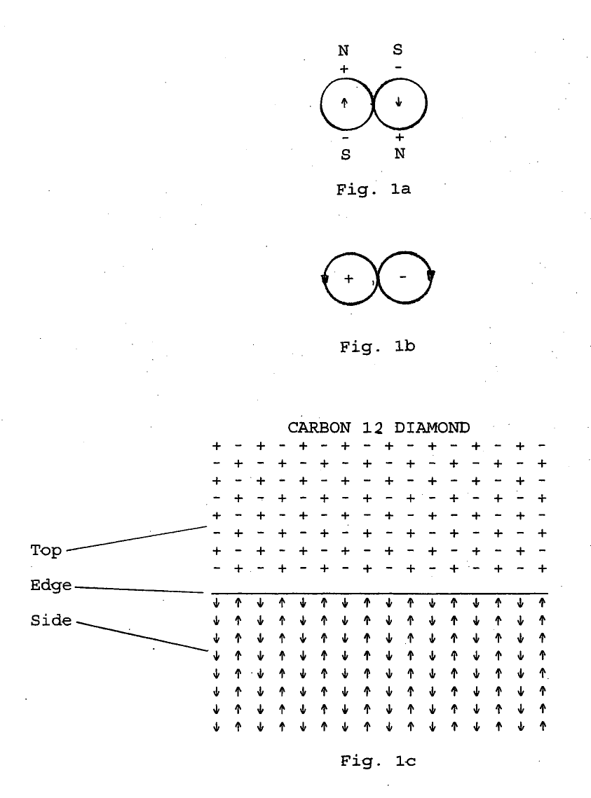

FIG. 1a shows two atoms with their valence electron paths touching and with their magnetic poles alternating so as to oppose each other in the second way that two magnets will hold together.

FIG. 1b shows two atoms with their valence electron paths touching and with their magnetic poles joined end to end in the first way that two magnets will hold together. Since two electrons cannot be at the point of touching at the same time, one electron is released for forming superconductivity.

FIG. 1c shows the top layer of carbon atoms with the magnetic polarity of each atom indicated by either a (+) sign or a (−) sign. Below the edge and looking at the side of a carbon diamond the magnetic poles of each atom is shown by an arrow pointing to carbon atom north poles. As explained under FIG. 1b, there is one superconducting electron floating within the crystal and not bonded to any carbon atom. Note that, looking down from the top, there one superconducting electron released for each touching valence electron ring in each direction thus one electron per carbon atom.

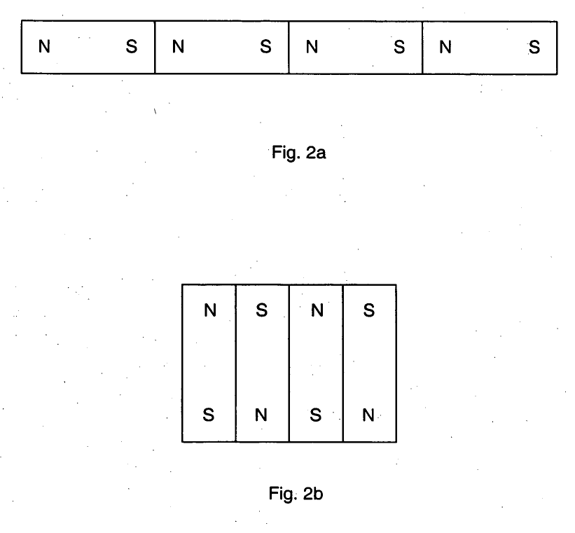

FIG. 2a show a string of magnets joined end to end. These could be physical bar magnets and can also be atomic magnets as in FIGS. 1a,b, and c. This is in a first way that magnets will join together in a stable form and represents the atomic situation on the side of the carbon diamond of FIG. 1c.

FIG. 2b shows the second of the two ways that magnets will bond and represents the situation on the top of the carbon diamond of FIG. 1c.

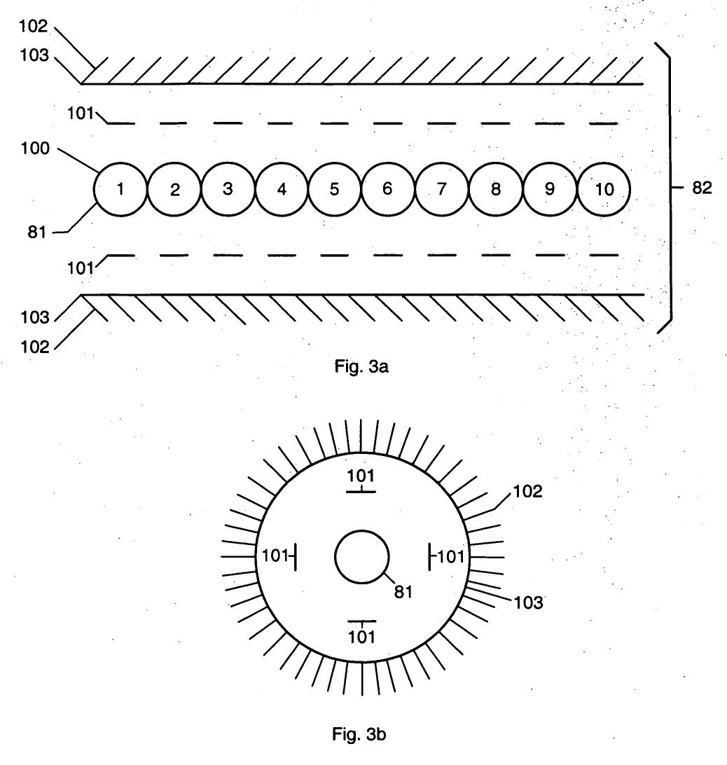

FIG. 3a shows ten carbon atoms, numbered 1 through 10 of a superconducting string 81 of carbon atoms. The atoms have their magnetic direction alternating along the string as in FIG. 1b. Carbon atoms are in a super-dense relation with their outer four valence electrons touching each other at a midpoint between each pair of atoms along the string. Since two electrons cannot be at this midpoint at the same time, one electron 101 per atom is ejected from the string and is held in superconductivity between the atoms of string 81 and the surface electrons 103 on the nanotube 102 surface of Delron plastic material.

FIG. 3b shows a cross section of carbon superconducting nanotube of any length. The body 102 carrying the superconducting nanotubes is preferably made of Rogers RT. Duroid 580 material. This material is a form of Teflon which is made slippery by having surfaces covered by electrons.

FIG. 3a shows the carbon atoms 81 at right angles to the view of FIG. 3b. The four valence electrons of carbon no longer flow around individual atoms but rather flow in a forward FIG. 8 wave pattern from right to left and back as backward reversed wave pattern from left to right. The electron required at the midpoint is alternatively furnished by the forward and then the backward electron currents. As can be seen, the electron at the midpoint is furnished by the forward current during the rising portion of its wave. The electron at the midpoint is furnished by the backward current during the falling portion of its wave thus the electrons 101 released to form superconducting current.

The magnetic force required by the nucleus of an atom such as carbon to hold its four outer valence atoms in orbit is derived as follows:
1. The force acting on a moving charge is given by: FB=qv×B where B is the magnetic field force vector.

The force symbol B is measured in Teslas.

One Tesla is defined as one Newton/(coulomb meter/second)

Since an Ampere is defined as one coulomb/second, therefore
2. 1 Tesla=1 Newton/Ampere meter

For a circulating charge, q, moving at right angles to a uniform magnetic field, the relationship is:
3. r=mv/qB

solving for B, the magnetic field yields:
4. B=mv/qr

For an electron orbiting a nucleus at an average radius of half the atomic diameter, the values would be:
5. B=(9.09×1031 kg) (3×10₈ meter/second)/((1.6×10⁻¹⁹ Coulomb) (0.5×10⁻¹⁰ meters) =3.41×10⁷^{₇} Tesla

This is the magnetic field necessary to constrain electrons to their orbit.

The force equal to the magnetic field of equation 5 is found from:
6. F=qv×B

F=(1.6×10⁻¹⁹^{_{−19}} Coul.) (3×10⁸ m/s) (3.41×10⁷ T.)

F=1.637×10⁻³ Newtons

since 4.45 Newtons equals approximately one pound:

F=3.68×10⁻⁴₋₄ pounds

Note that this is the force that the valence electrons exert on the nucleus.
7. C12 has 12 neutrons and protons in the nucleus thus has a mass of 12.

The difference in mass of a neutron or proton and an electron is approximately 1840.

The magnetic field of the nucleus that attracts electrons and holds them in orbit, is therefore:

F=(3.68×10⁻³)×12×1840

F=8.13 pounds

Note that these forces have a direction but, like a rubber band, have no beginning or end. This then is the force between two atomic cores, acting as bar magnets, located side by side with magnetic fields alternating in direction in a first of two stable orientations of two closely bonded atoms. The same force holds two atoms together with their fields joined head to tail in the second of two stable orientations of two closely bonded atomic cores, acting as bar magnets.

The current that can be carried by a superconducting carbon string is calculated as follows:

Assuming that the superconducting electrons flow at the speed of light along the outside of the carbon string, one can derive the current flow along a single string 81:
1. The diameter of a carbon atom is approximately 1×10⁻¹⁰ meters.
2. The speed of light is 3×10⁸^{₈} meters/second.
3. The transit time across each C12 atom is distance/velocity=1×10⁻¹⁰^{_{−10}}/3×10⁸^{₈} meters per second=3.33×10⁻¹⁹ seconds.
4. The number of electrons passing any point along string 81= 1/3.33×10⁻¹⁹=3×10¹⁸^{_{−18}}
5. One Ampere 1 coulomb/second.
6. One Coulomb=6.24×10¹⁸^{₈} electrons.
7. The maximum current along a single string 81 is therefore: 6.24×10¹⁸/3×10¹⁸=2.08 Amperes.

As shown in FIGS. 2a and 2b, one can conceptually duplicate the structure of closely bonded C12 diamonds using a number of bar shaped permanent magnets.

FIG. 2a shows four bar magnets joined at NS of SN boundaries in the first way that bar magnets may join together.

FIG. 2b shows four bar magnets joined together in the second way that bar magnets may join together at NS or SN boundaries.

Two planes of such magnets can be made in 4×4 patterns of 16 magnets each. When four such planes are placed one above the other, a very strong cube structure results conceptually duplicating the super-dense form of carbon diamonds.

FIGS. 3a and 3b show a superconducting nanotube 82. FIG. 3a shows a superconducting string 81 of 10 carbon atom valence electron circular paths numbered 1 through 10. Said forward and backward valence electrons flowing in circular paths 100 flow as described under FIG. 1b. Said superconducting electrons 101 first shown under FIG. 1b are shown flowing in the space in FIGS. 3a and 3b between string 81 and Delron (teflon-like) plastic tube 102. It is the nature of said Delron plastic to have a layer 103 of electrons on its surface. Said electron flow 100 on the surface of string 81 together with said electron charged surface 103 repel said superconducting electrons 101 to a midpoint between the nanotube surface 103 and string 81. Note that superconductive currents can flow in either direction of nanotubes 82, but not in both directions at the same time.

Unlike electron paths in single carbon atoms, when in the dense diamond form the electrons follow paths perpendicular to the directions of the magnetic fields shown as in FIG. 1b. These paths overlap with the magnetic fields holding all electrons in planes parallel to the top. The forces make 180° turns at the ends of each row across or front to back of the top of the diamond.

Down the side, one sees the magnetic forces of carbon atoms going down from top to bottom and returning in adjacent paths from bottom to top. Each two such paths reverse direction and return at the top and bottom thus completing a “rubber band” of magnetic force lines.

The edge defines the 90° break between the top and the side of the C12 diamond. Arrows in the first row below the edge show the alternating magnetic fields of the atoms of each horizontal layer of the diamond. Horizontal atomic layers of the diamond are identical to each other. Each layer shows that the magnetic fields of the atoms attract each other end to end in the second of the two ways that magnetic fields of atoms stably attract each other.

It is necessary to terminate said superconducting string 81 on both ends with super-dense carbon diamonds capable of sending and receiving said forward and backward electron currents 100. Currents termed forward at one terminating end are considered backward at the other terminating end. The top of FIG. 3 shows rows of carbon atoms with magnetic atomic polarity alternating from pointing up (+) and down (−). Atomic layers identical to the top layer are stacked one above the other with atomic polarity all pointing up (⇑) in one column or all pointing-down (↓) in alternate columns.

Valence electron bands touch as in FIGS. 1a and 1b but in three dimensions. There are no electron repulsion between atoms in the super-dense carbon diamond adding to the magnetic coupling between adjacent and atoms giving hardness 10,000 times that of ordinary carbon diamonds. Moreover superconducting electrons abound within the super-dense diamond capable of carrying superconductive currents in any direction.

It is necessary to terminate superconductive strings with super-dense carbon terminating plates. The following discussion estimates that 10,000 strings can be spaced across a one centimeter terminating plate.

The diameter of the path of four outer electrons in carbon atoms is 10⁻¹⁰ meters. Considering one centimeter a practical width of a terminating plate, there are 10⁸=100 million atoms across a one centimeter super-dense carbon diamond. If a superconductive ribbon had 10,000 carbon strings side by side they can be spaced every 10⁴^{₄}=every 10,000 atoms across a one centimeter terminator. The ribbon cable is brought out from a single layer of a super-dense carbon diamond plate. With 500 layers of super-dense carbon diamond added on either side of the layer connected to superconducting strings a one millimeter thickness plate results.

It is necessary for said teflon like plastic nanotubes 82 to touch the surface of the terminator plate. The distance of 10,000 atoms between superconducting strings is adequate for this requirement.

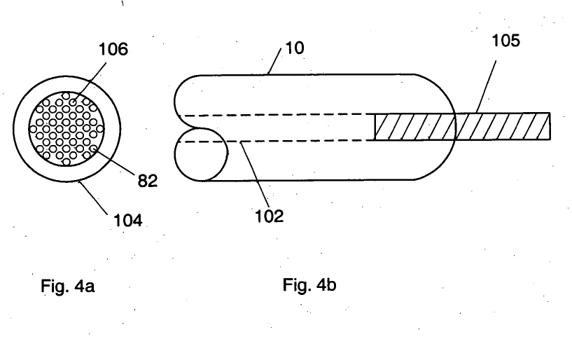

FIG. 4 shows a super-dense terminating plate 105 for a superconducting cable 104 such as might be used to carry electric power in an electric power utility application. The cable has many superconducting carbon strings 100 each in a Delron tube 82. Please return to FIGS. 3a and b for details of a single superconducting string.

A cable, constructed as described herein, can be vibrated longitudinally as a means of sending information. The stiffness of the cable indicates messages can be sent by modulation of longitudinal vibrations using various well known methods of encoding into such vibrations.

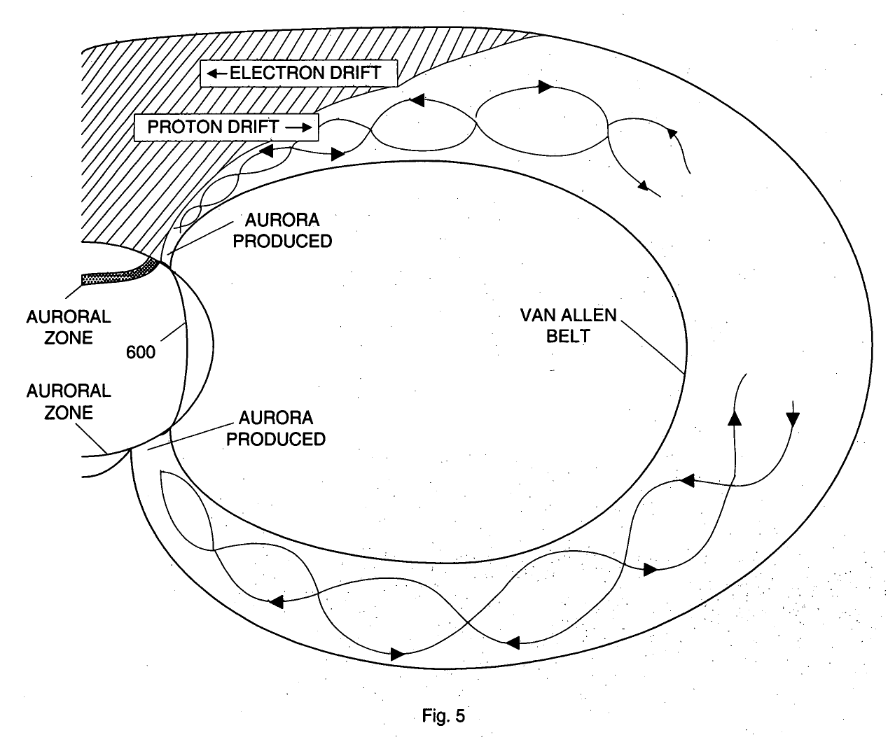

FIG. 5 was taken from reference U.S. Pat. No. 4,042,196 with inventive portions removed. This is typical of references to belts of electric current that must pass through the Earth as currents 600 and then take a path away from Earth in the northern hemisphere and returning in the southern hemisphere. A Jun. 23, 2006 notes from NASA titled Radiation Belts shows trapped particles following magnetic fields of the Earth, much as shown by FIG. 5. One must recognize that FIG. 5 is a partial cross section of a donut effect circling the Earth.

The NASA article shows rotation of particles around magnetic lines much as shown in FIG. 5. Could this rotation supply the energy to cause tornados? Could winds blow the belts across the country carrying the tornados down ‘Tornado Alleys’?

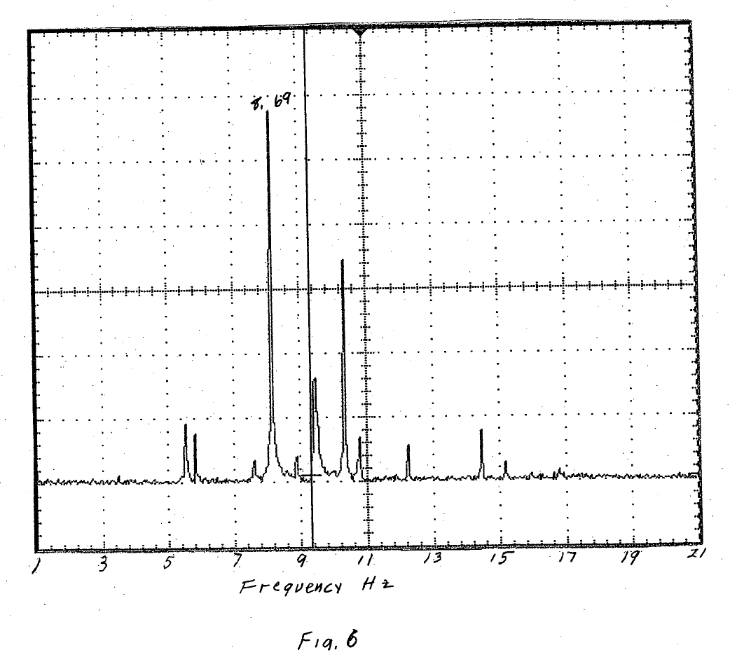

FIG. 6 shows a spectrum of signals found under the earth using techniques described in provisional patent 60/809,62 filed in the name of the present inventor.

The peak marked 8.69 Hz is believed to be a current flowing underground more or less in the plane of the equator. This peak has the least variation in frequency and amplitude. The relation between frequency and current appears to be that the frequency represents a modulation of a current.

The signals between 9 and 11 Hz change rapidly and appear to be from volcanos and earthquakes.

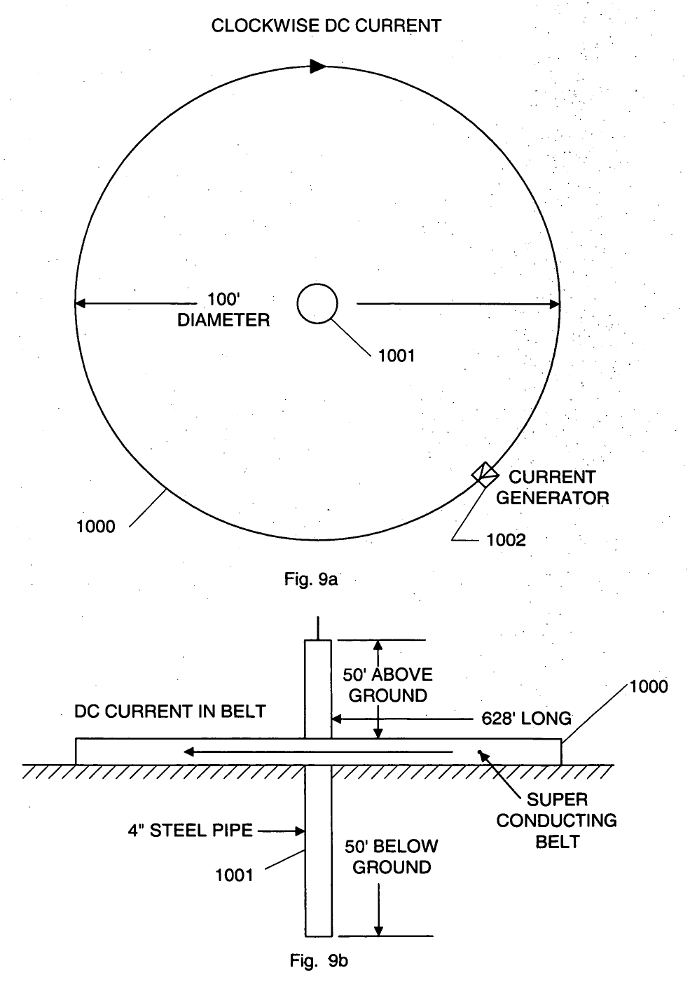

The peaks between 11 and 15 Hz change daily and are believed to be flowing parallel to the line between magnetic poles of the Earth. They may supply the energy that feeds tornados. Since these peaks flow at right angles to the peak marked 8.69 Hz., these currents may create vortexes that may lay under hurricanes and feed energy to them. If so this supports the use of the system described under FIG. 9.

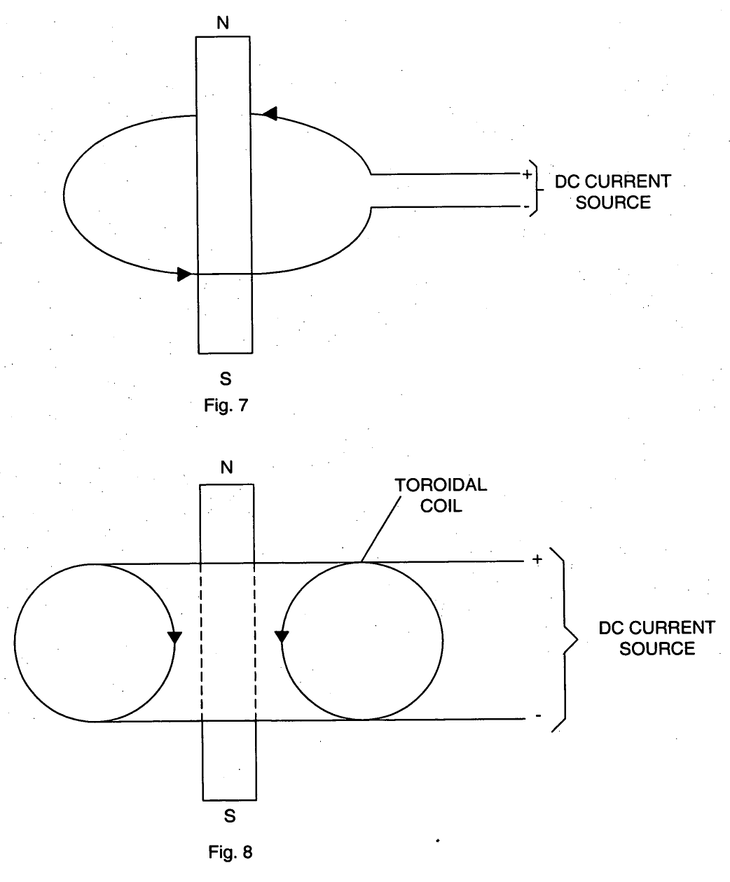

FIG. 7 shows a first way that a dc current can form the north and south poles of a magnetic bar. This may be analogous to a current under the equator can partially support the Earth's magnetic poles.

FIG. 8 shows a second way that a dc current can form poles of a magnetic bar. This may be analogous to the effects of currents 600 flowing through the Earth from the sources described in FIG. 5.

The currents under the surface of the Earth from the effects described under FIG. 7 and FIG. 8 cross at right angles. Do these not create vortexes under the Earth that could become synchronous with hurricanes and feed energy to the hurricanes?

Hurricanes may be found to contain large magnetic fields. If so it should be possible to place superconducting cables capable of carrying as much as one million amperes in the clockwise direction. Such cables could suck energy from a hurricane as it passes overhead. Means for dissipating this energy so as to maintain the clockwise current could dissipate clockwise rotating storms before they go into heat sources such as the Gulf of Mexico.

Other high current superconducting cables could be located in the lower Atlantic carrying counterclockwise currents to create hurricanes in order to cool the Earth with acceptable inconvenience to shipping. Combinations of these two types of current loops can be studied by expert organization and controlled by those organizations if these ideas are found feasible. The organizations presently controlling carbon superconductor technology may find it desirable to lead in use of the technology by those of us denied access to carbon superconductor manufacturing facilities.

FIG. 9 illustrates a Storm Energy Reducing System (SERS) for taking energy out of hurricanes to reduce their destruction. The SERS may also be useful using a number of installation along the equator for dissipating the earth's energy and thus controlling global warming.

The SERS consists of a superconducting belt 1000, a 4 inch steel pipe 1001 and a current generator 1002. The superconducting belt shows on pages 21 and 22 of the Reference 1 document describing the CARDINAL MHC ship. The belt is showing coming from a cylindrical container as it forms the plastic body of the Cardinal. The dimensions shown on FIG. 9 are approximate but will be as used in building the Cardinal and her sister ships. Both the belt 1000 and the current generator 1002 will be obtained from Intermarine SpA of Le Spezia Italy.

It is believed that when energized under a storm cloud having a magnetic field a continuous spark (not really lightning since there is no leader stroke from the sky) will form from the top of steel pipe 1001 removing energy from the cloud. It seems necessary that the current flow through the belt in a clockwise direction in the northern hemisphere. It is believed that energy taken from the cloud will be dissipated as heat by the spark itself.

A second use for the SERS could be to generate storms at the equator to continually take energy from equatorial regions and balance the Earths' heat loss in a controlled way lasting thousands of years.

The following article is taken from a publication by “The New Mexico Facetor” summarizing a speech by Dr. Ralph Dawson: “Program Speaker: Dr. Ralph Dawson, Crystal Grower. By Drs. Scott and Susan Wilson. This is included in the belief that Dr. Dawson and others at his employer, Sandia Laboratories are familiar with carbon superconductors and their manufacture.

Dr. Ralph Dawson, who recently retired from Sandia National Laboratories as a crystal grower, spoke to the Guild about basic crystal classes and their unique crystal lattice arrangements. For thirty years, Dr. Dawson grew crystals using a technique known as molecular beam epitaxy (MBE). Molecular beam epitaxy allows the crystal grower to precisely grow very thin layers of atoms (known as mono-layers) with controlled thickness. This technique permits highly advanced semiconductors structures to be grown, such a Vertical Cavity emitting Lasers (VCELs).

The materials that Dr. Dawson works with are mainly III-V compounds. These are binary (2 component) chemical compounds formed from one element taken from the 3rd column of the periodic table, along with one element taken from the 5th column of the periodic table. Hence, the name “three-five compounds”. Examples of these types of compounds are Gallium-Arsenide (GaAs) and Indium-phosphide (InP). These compounds are of great interest in the manufacturing of semiconductor lasers (your CD player has one). In his introduction, Dr. Dawson described the three degrees of crystallization that a solid material may take: amorphous, polycrystalline, and a single crystal. The differences between these three types are based upon the size of an ordered region within the material.

An ordered region is a volume within where the atoms (or molecules) exhibit regular geometric or periodic arrangements. Amorphous material, such as glass, has order only on a length scale of a few atoms (very, very small). In both cases above, the ordered regions vary in size and orientation with respect to each other (rotated or displaced). Single crystal material, mainly what we faceters work with, has a high degree of order over a long range (several millimeters).

A single crystal region is called a grain. Adjacent crystal grains are separated by grain boundaries. These grain boundaries effect how well a material conducts electricity, and they may also influence the strength of the material.

The periodic arrangement of the atoms in the single crystal is called the “lattice”. The 3D lattice is a periodic repetition of atoms. Since the lattice structure has repetitions within, there must be a group of atoms. Since the lattice structure has repetition within, there must be some fundamental unit being repeated across the whole lattice. This fundamental unit is called the unit cell. By stacking unit cells above, below, and next to each other, we can build the full lattice structure to fill any given volume in the crystal.

There are seven crystal systems: triclinic, monoclinic, orthorhombic, tetragonal, cubic, hexagonal, and trigonal. fourteen possible unit cells exist and are known collectively as the Bravis lattices. Two things need to be kept in mind: which crystal system and which unit cell structure.

Dr. Dawson explained the symmetry found in as crystal. Since the crystal is formed with repeating unit cells, it logically follows that there will be some symmetry in the arrangement of the crystal lattice.

The crystal symmetry can be seen by rotating models of the different crystal lattice structures. for example, if the crystal structure is cubic, then the lattice will look like a box with an atom at each corner of the box. If we hold the box to look only at the front of the box, then we only see four atoms (one at each corner). If we rotate the box to look at one of the other sides, it will .appear exactly the same to us. There is no visible difference in the four sides. This is an example of four-fold symmetry.

To satisfy interests of the group, Dr. Dawson spoke about cleavage planes in material. Crystals will cleave (break apart along crystal planes) where the atomic bonds are weakest. Bond strength is a function of the distance between adjacent atoms. The closer the atoms are to each other, the stronger the bond. Dr Dawson mentioned that one must take into account the density of the bonds on adjacent layers. For example, on a given crystal plane, the bond strength between the atoms on either side of the plane may be weak. However, many atoms may be connected together across the plane and prevent the crystal from cleaving along that plane. Those bonds may be weak, but there are a lot of them.

There is one crystal lattice arrangement that Dr. Dawson identified as THE most technologically important for mankind: the diamond structure. Clearly the diamond structure is that exhibited by diamonds, with the lattice points being carbon atoms. Other materials may crystallize in the diamond structure, and among them is the element silicon. Silicon is used extensively in the semiconductor industry to make all of the integrated circuits and transistors that run our computers, cars, phones, and our lives.”

### ADVANTAGES OF AND PROBLEMS WITH THE INVENTION

1. Superconducting strings for carrying electric currents without the need for cryogenic cooling will eliminate voltage drops and power losses in electric power transmission and distribution lines. This can save as much as $100 billion per year and contribute to reducing global warming.
2. Superconducting strings for carrying electric currents without the need for cryogenic cooling will eliminate power losses in electric power generators and transformers. This can further contribute to reducing global warming.
3. At http://www.metropolismag.com/html/content_{—}0203/fib/ Peter Testa Architects describe buildings of the future which use no concrete or steel but rather use plastics and ceramics to suggest buildings that are very strong but also very light as compared to present technology.

It is interesting to assume the success of the present invention and the future use of cables of say 10,000 parallel strands of carbon strings. This could be equivalent to a square bundle of 100×100 strings. These bundles would be 10⁻⁸ meters square in size, still too small to see with ordinary light. If 10,000 strings, each in a plastic nanotube, are spread across a one centimeter ribbon cable the cable could carry 20,800 amperes of current from building to building. The cables would also have a strength of 8.13 lbs per strand multiplied by 10,000 strands for a pull strength of 81,300 pounds! Such cables could supply bracing for the buildings and support catwalks between buildings at levels above street level. At the same time electric power can be distributed among the buildings over the cables. Some cables might carry 3 Vdc for computers. Other cables might carry 24 Vdc for lighting, air conditioning, etc.

If the carbon string technology is applied to end use devices further changes may be contemplated. The power efficiencies of end use devices can be improved greatly reducing the energy required per person using the buildings.
4. SERS systems can be installed at the equator and used in a regulated way
5. The most serious problem is in obtaining release of security by the National Security Agency or other agencies responsible for such action. Humans and others may block this release.

While the invention has been particularly shown and described with reference to preferred embodiments thereof, it will be understood by those skilled in the art that various changes in form and details may be made therein without departing from the spirit and scope of the invention.

What I claim is:

1. An assembly of atomic strings comprising in combination:
a) means for forming carbon atom strings with valence electrons touching,
b) string construction means for forming strings with the core magnetic directions of said atoms alternating from up to down,
c) string construction means for placing said carbon atoms with their valence electron orbits touching each other at midpoints between atoms along said strings thus ejecting an electron from each midpoint,
d) super-dense carbon diamond termination plate means for terminating both ends of multiple said strings,
e) carbon string to super-dense carbon diamond termination plate connection means for providing valence electron flows in both directions between ends of said carbon strings, and
f) crossing said valence electron flows at said midpoints between atoms whereby the electrons at said midpoints between atoms are alternately furnished by one and then the other of the valence electron current flows.

2. An assembly of atomic strings as in claim 1 with said string construction means using molecular beam epitaxy technology.

3. An assembly of atomic strings as in claim 1 further comprising in combination:
a) plastic means for holding said multiple strings in parallel ribbons, and
b) surface means for said plastic for forming negatively charged nanotubes around each said multiple string permitting said ejected electrons to flow between terminating plates as superconducting currents in the spaces between said strings and said nanotubes.

4. An assembly of atomic strings as in claim 3 further comprising in combination a second plastic means for placing an outer protective cover over said multiple strings in parallel ribbons between terminating plates thus forming a superconductive cable.

5. Superconductive cables as in claim 4 further comprising vibrational communications means for communicating via longitudinal vibrations along said cable.

6. An assembly of atomic strings as in claim 1 further comprising in combination:
a) said plate termination means for connecting multiple said strings to one layer of super-dense carbon diamond for producing valence electron flow in both directions between ends of said carbon strings, and
b) additional layers of super-dense carbon diamond means for adding above and below said one layer of super-dense carbon diamond thus forming a termination plate of useful thickness.

7. A method of producing wide temperature range superconducting cables, said method comprising the steps of:
a) forming strings of carbon atoms having alternating directions of atomic magnetic force along said string,
b) forming said strings with valence electron paths of carbon atoms touching at midpoints between each pair of atoms along said string thus ejecting one electron from each midpoint,
c) forming super-dense carbon diamond terminating plates at both ends of multiple strings for furnishing valence-electron flows in either direction between said terminating plates,
d) forming nanotubes of special plastic around each multiple string having electron surfaces on insides of said nanotubes, and
e) terminating said nanotubes at terminating plates for permitting said ejected electrons to flow as superconductive current in either direction between said terminating plates.

8. A Storm Energy Reducing System (SERS) comprising the following in combination:
a) a carbon superconducting belt laid on edge on the ground for carrying large currents, and
b) a vertical steel pipe means for sending sparks into storm clouds for withdrawing energy from the clouds
